(19) United States
(12) Patent Application Publication
(10) Pub. No.: US 2017/0286216 A1
(43) Pub. Date: Oct. 5, 2017

(54) ENERGY EFFICIENT READ/WRITE SUPPORT FOR A PROTECTED MEMORY

(71) Applicant: Intel Corporation, Santa Clara, CA (US)

(72) Inventors: Vivek Kozhikkottu, Hillsboro, OR (US); Dinesh Somasekhar, Portland, OR (US); Young Moon Kim, Hillsboro, OR (US); Sang Phill Park, Hillsboro, OR (US)

(73) Assignee: Intel Corporation, Santa Clara, CA (US)

(21) Appl. No.: 15/089,340

(22) Filed: Apr. 1, 2016

(51) Int. Cl. G06F 11/10; G06F 3/06; G11C 29/52

(52) U.S. Cl. CPC G06F 11/1068; G11C 29/52; G06F 3/0619; G06F 3/064; G06F 3/0679

(57) ABSTRACT

Technology for an apparatus is described. The apparatus can include a memory controller with circuitry configured to read K bits of M bits of encoded data in memory, D error detection bits, and P Parity bits protecting the M bits of encoded data for performing a read-write-modify (RWM) command operation on the K bits of the M bits encoded data, wherein K, M and D are positive integers and P is a vector of a set of parity bits. The memory controller can determine whether an error is present on the K bits of the M bits of encoded data according to the D error detection bits.

### BACKGROUND

Memory devices are typically provided as internal, semiconductor, integrated circuits in computers or other electronic devices. There are many different types of memory including volatile memory, for example, dynamic random access memory (DRAM) and synchronous dynamic random access memory (SDRAM), and non-volatile memory (NVM), for example, flash memory or phase change memory.

Flash memory devices typically use a one-transistor memory cell that allows for high memory densities, high reliability, and low power consumption. Changes in threshold voltage of the cells, through programming of a charge storage node (e.g., a floating gate or charge trap) determine the data state of each cell. Other non-volatile memories such as phase change memory (PCM) use other physical phenomena such as a physical material change or polarization to determine the data state of each cell. Common uses for flash and other solid state memories include personal computers, personal digital assistants (PDAs), digital cameras, digital media players, digital recorders, games, appliances, vehicles, wireless devices, cellular telephones, and removable portable memory modules among others. The uses for such memory continue to expand.

### BRIEF DESCRIPTION OF THE DRAWINGS

Features and advantages of technology embodiments will be apparent from the detailed description which follows, taken in conjunction with the accompanying drawings, which together illustrate, by way of example, technology features, wherein:

FIG. 1 is a block diagram of an error correction code data scheme in accordance with an example embodiment;

FIG. 2 depicts a flowchart of a method for performing a traditional partial write operation in accordance with an example embodiment;

FIG. 3 depicts a flowchart of a method for performing a partial write operation on K bits of memory protected at an M bit granularity with P bits of parity in accordance with an example embodiment;

FIG. 4 depicts a flowchart of a method for performing a partial read operation on K bits of memory protected at an M bit granularity with P bits of parity in accordance with an example embodiment;

FIG. 5 depicts a flowchart of a method for performing a read-write-modify (RWM) command operation on K bits of memory protected in accordance with an example embodiment;

FIG. 6 depicts a flowchart of an additional method for performing a read-write-modify (RWM) command operation on K bits of memory protected in accordance with an example embodiment;

FIG. 7 depicts a flowchart of an additional method for performing a read-write-modify (RWM) command operation on K bits of memory protected in accordance with an example embodiment;

FIG. 8 illustrates a memory system diagram in accordance with an example embodiment; and

FIG. 9 illustrates a computing system that includes a data storage device in accordance with an example embodiment.

Reference will now be made to the exemplary embodiments illustrated, and specific language will be used herein to describe the same. It will nevertheless be understood that no limitation on disclosure scope is thereby intended.

### DESCRIPTION OF EMBODIMENTS

Before the disclosed embodiments are described, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular examples or embodiments only and is not intended to be limiting. The same reference numerals in different drawings represent the same element. Numbers provided in flow charts and processes are provided for clarity in illustrating steps and operations and do not necessarily indicate a particular order or sequence.

Furthermore, the described features, structures, or characteristics can be combined in any suitable manner in one or more embodiments. In the following description, numerous specific details are provided, such as examples of layouts, distances, network examples, etc., to provide a thorough understanding of various technology embodiments. One skilled in the relevant art will recognize, however, that such detailed embodiments do not limit the overall inventive concepts articulated herein, but are merely representative thereof.

As used in this specification and the appended claims, the singular forms “a,” “an” and “the” include plural referents unless the context clearly dictates otherwise. Thus, for example, reference to “a bit line” includes a plurality of such bit lines.

Reference throughout this specification to “an example” means that a particular feature, structure, or characteristic described in connection with the example is included in at least one invention embodiment. Thus, appearances of the phrases “in an example” or the like in various places throughout this specification do not necessarily all refer to the same embodiment.

As used herein, a plurality of items, structural elements, compositional elements, and/or materials can be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various invention embodiments and examples can be referred to herein along with alternatives for the various components thereof. It is understood that such embodiments, examples, and alternatives are not to be construed as defacto equivalents of one another, but are to be considered as separate and autonomous representations under the present disclosure.

Furthermore, the described features, structures, or characteristics can be combined in any suitable manner in one or more embodiments. In the following description, numerous specific details are provided, such as examples of layouts, distances, network examples, etc., to provide a thorough understanding of invention embodiments. One skilled in the relevant art will recognize, however, that the technology can be practiced without one or more of the specific details, or with other methods, components, layouts, etc. In other instances, well-known structures, materials, or operations may not be shown or described in detail to avoid obscuring aspects of the disclosure.

In this disclosure, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the compositions nature or characteristics would be permissible if present under the “consisting essentially of” language, even though not expressly recited in a list of items following such terminology. When using an open ended term in this specification, like “comprising” or “including,” it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that any terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

As used herein, comparative terms such as “increased,” “decreased,” “better,” “worse,” “higher,” “lower,” “enhanced,” “improved,” and the like refer to a property of a device, component, or activity that is measurably different from other devices, components, or activities in a surrounding or adjacent area, in a single device or in multiple comparable devices, in a group or class, in multiple groups or classes, or as compared to the known state of the art. For example, a process that provides “improved” efficiency is a process that requires less time or energy to perform the process than to perform the same or a similar state of the art process. A number of factors can cause such increased risk, including location, fabrication process, number of program pulses applied to the region, etc.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint. However, it is to be understood that even when the term “about” is used in the present specification in connection with a specific numerical value, that support for the exact numerical value recited apart from the “about” terminology is also provided.

Numerical amounts and data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 1.5, 2, 2.3, 3, 3.8, 4, 4.6, 5, and 5.1 individually.

This same principle applies to ranges reciting only one numerical value as a minimum or a maximum. Furthermore, such an interpretation should apply regardless of the breadth of the range or the characteristics being described.

### Example Embodiments

An initial overview of technology embodiments is provided below and then specific technology embodiments are described in further detail later. This initial summary is intended to aid readers in understanding the technology more quickly, but is not intended to identify key or essential technological features nor is it intended to limit the scope of the claimed subject matter. Unless defined otherwise, all technical and scientific terms used herein have the same meaning as commonly understood by one of ordinary skill in the art to which this disclosure belongs.

Computing systems may have different kinds of memory, such as, for example, static random access memory (SRAM), dynamic random access memory (DRAM), read only memory (ROM), erasable programmable read-only memory (EPROM), volatile and non-volatile random access memory (RAM), non-volatile memory (NVM), flash memory, such as NAND or NOR memory, phase change memory (PCM), and 3D Xpoint memory among others. Solid state drives (SSDs) are storage devices that use integrated circuit assemblies as memory to persistently store data. SSDs do not have moving parts (i.e., no moving mechanical components) and can retain data without power. SSDs typically utilize non-volatile memory, for example NAND or PCM. NAND can be single level cell (SLC) NAND, which encodes a single bit of information per cell, or multiple level cell (MLC) NAND which encodes more than one bit of information per cell. For example, in triple level cell (TLC) NAND, three bits of information are stored per cell.

Computing systems can include on-chip memory (e.g., components built on the chip (IC) itself) and/or Off-chip memory (e.g., discrete components that are not built on a chip). One type of on-chip memory and/or off-chip memory, is scratchpad memory (SPM), also known as scratchpad or scratchpad RAM. A scratchpad memory can be a high-speed internal memory used for temporary storage of calculations, data, and other work in progress. In reference to a microprocessor (“CPU”), scratchpad can refer to a special high-speed memory circuit used to hold small items of data for rapid retrieval. For example, the scratchpad memory can be similar to the usage and size of a scratchpad in life: a pad of paper for preliminary notes or sketches or writings, etc. In short, scratchpad memory can be local, high-speed memories that are manually controlled by the application. By precisely controlling data movements to and from scratchpads, applications can maximize performance, utilization, and energy efficiency.

In one aspect, scratchpad memories or caches can be protected by: 1) protecting the scratchpad memories or caches at fine 8 Byte load/store units (LD/ST) granularity, which can incur a 12.5/25% single-error-correct, double-error-detect (SECDED) a double-error-correct, triple-error-detect (DECTED) (SECDED/DECTED) area and can incur a significant energy consumption overhead for read and write operations. Also, the scratchpad memories or caches can be protected by 2) protecting the scratchpad memories or caches at a large cache line granularity size, such as a size of 64 Bytes, which can incur a significant energy consumption overhead (e.g., up to 8 times “8×” increased computing energy consumption) for partial reads and writes.

Use of linear block error correction codes in computing system memory can lower overhead, elevate performance and have relatively easy implementation. However, the full potential of linear block error correction codes has not been realized due to the fact that: 1) the linear nature of the linear block error correction codes have not been exploited, 2) low overhead updates of a parity field under partial writes, such as when only a selected portion of the data protected by the linear block error correction code is modified) are not typically performed, and 3) energy is not conserved on partial reads to a memory by utilizing low overhead error detection-only-bits (e.g., a parity bit suitable for detecting errors) at a finer granularity.

Various embodiments reliably protect memory, such as scratchpad memories, and caches from errors, such as soft-errors where a signal or datum is wrong. Accordingly, the various embodiments provide detection-only-parity bits at selected locations (e.g., a defined, repeated locations), such as having the detection-only-bits placed every 8 Bytes (1-3% area overhead) in memory. By having detection-only-bits repeatedly occurring following every 8 Bytes, for example, the detection-only-bits can be used for detecting and correct errors and can work with any linear block code. In one aspect, for example, the detection-only-bits can protect a large Byte granularity size (e.g., 32 and/or 64 Bytes) such as, for example, SECDED, DECTED, and/or single-error-correct, quadruple adjacent error correction (SECQAEC), and can be up four-to-eight times (4×-8×'s) more energy efficient than read-modify-write (RMW) based schemes. Moreover, unlike current memory implementations (e.g., a cache implementation), where data is accessed and updated at large line size granularities and are often written and read at multiple granularities (e.g., 8 bites (B), 32B, 64B), the various embodiments can eliminate the high overhead of ECC protection at the smaller granularity size level (e.g., 64 bit), reduces exorbitant energy overhead and processing power of performing Read-Modify-Write (RMW) operations on the entire lines of data in memory, and/or protects the lines of data that have partial writes.

In one aspect, systematic linear block codes can be used to cover a large variety of hardware parity codes used to protect memories. The parity “P” can be written as the equation (1) (including a generator matrix) of:

$$P = [ {m}_{1} , {m}_{2} , … , {m}_{n} ] * \vert \begin{matrix}… {G}_{1} … \\ … {G}_{2} … \\ … {G}_{n} …\end{matrix} \vert , \qquad ( 1 )$$

where, m₁ to mₙ are data bits that are to be encoded, and G₁ to Gₙ are corresponding rows of the generator matrix. The number of columns that are in the generator matrix depends on the number of bits of parity P needed by the code (e.g., 10 columns for single-error-correct single-error-detect “SECSED” code protecting 512 bits). However, due to the linear nature of the operations involved in this transformation, equation 1 can be rewritten as equation (2):

P=P₁,K+PK+1,2K+ . . . Pₙ−K+1,n [symbol] (2),

where K and n can be positive integers, and P₁,K corresponds to the parity bits generated by utilizing the first K bits of data, and PK+1,2K corresponds to the parity bits generated by data bits K+1 to 2K, and so forth. It should be noted that the additions of equation (1) and/or equation (2) can occur in a F2 field (e.g., a Galois field of two elements or “F2”) and can be XOR operations of an XOR logic circuit. Consider now a scenario where n bits of data [m₁, mₙ, . . . , mₙ] in the memory are be protected by a set of parity bits denoted by the vector P and it is desired to modify the first K bits of a messages [m₁, mₙ, . . . , m_{K}]. Accordingly, the original parity can be rewritten as equation (3):

P=P₁,K+PK+1,n [symbol] (3),

and a new parity (P^{new}) can be written (following a series of equation combinations) as:

P^{new}=P₁,K^{new}+PK+1,n (4),

P^{new}=P+P₁,K+P₁,K^{new} and combine (3) and (4) for (5),

P^{new}=P+M^{new}_{1,k}+G_{1,K}+M_{1,K}*G_{1,K} (6),

P^{new}=P+M^{new}_{1,K}+G_{1,K}+M_{1,K}*G_{1,K} (7),

where from Equation (7), it can be observed that a computation of the new parity P^{new} [symbol] an eliminate the need to use message bits from (K+1) to n (e.g, MK+1,n).

Thus, the various embodiments can eliminate the need to read those bits out of memory (e.g., message bits from (K+1) to n) and thereby increase a savings in energy consumption.

In one aspect, the new parity P^{new} update operations, as described above, can be constrained to be valid only as long as there are no present or current errors in the bits that are to be modified. Thus, the various embodiments can provide an additional solution to detect whether the K bits, which are to be modified and/or in the process of being modified, have an error.

In one aspect, the various embodiment can provide “D” parity bits every K bits of data, where K is the granularity level at which the partial updates are performed in the memory and “D” can be a positive integer and can be a set of parity bits based on the detection capability of the memory. It should be noted that in one aspect, the D parity bits can be used for detecting and correcting errors. Alternatively, the “P” parity bits can be used for detecting and correcting errors. In an additional aspect, both the P parity bits and the D parity bits can be used for detecting and correcting errors.

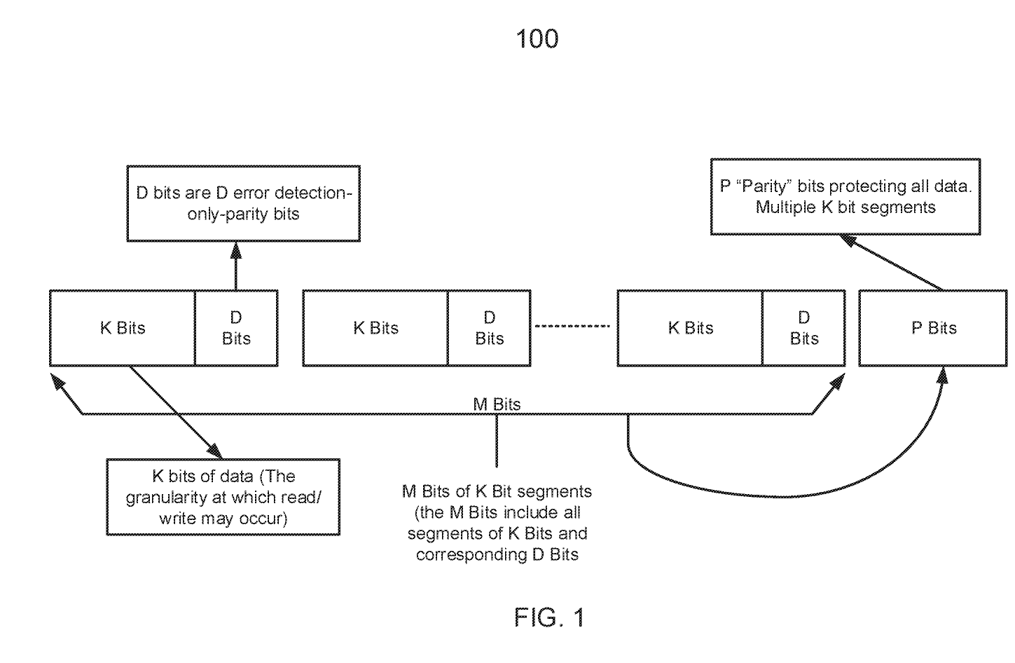

FIG. 1 shows a block diagram of an error correction code (ECC) data scheme. More specifically, FIG. 1 illustrates an ECC data scheme for performing partial line updates in ECC protected memories in both partial write and partial read scenarios and the corresponding energy benefits. As shown, FIG. 1 illustrates K bits of data segments that make up the M bits of encoded data in memory. The M bits are the entire line of data or one or more of the K bits that make up the entire line of data. D error detection-only parity bits can be placed and located adjacent to each segment of K bits. At the end of the M bits, P parity bits can be adjacently located to protect an entire data segment of one or more K bit segments. That is, the P parity bits are adjacently located next to the end of the M bits. The K bits of data can be the granularity for performing a read/write operation.

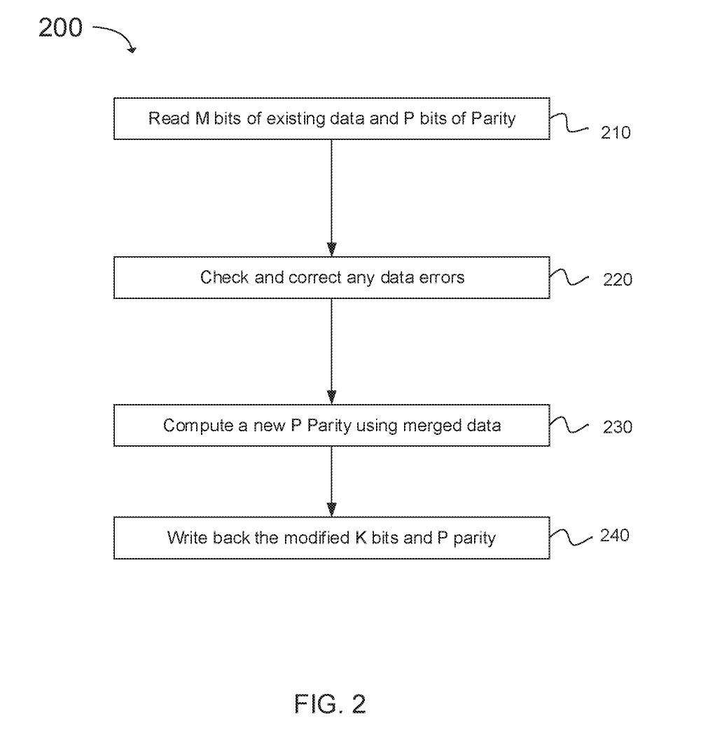

FIG. 2 depicts a partial write operation without the use of equation (7) and ECC data scheme of FIG. 1. For a partial write operation (e.g., where it is desired to write a subset of the K bits of data of an entire set of M bits, as depicted above in FIG. 1, in a traditional RMW operation, the entire M bits of old data (e.g., existing data in memory) and Parity P bits are read out of the memory, as in block 210. Next, a determination is made to check and correct if any bits are in error, as in block 220. The new data is merged with the old data (e.g., modified data) and a new parity P is computed, as in block 230. The modified K bits of data and the P Parity bits are written back to the memory, as in block 240. However, in order to modify only the K bits, a computing system is constrained to have to read the entire line of M bits and the Parity bits (e.g., M+P bits), followed by a write of all the M bits and the Parity bits (e.g., M+P bits) making it highly energy inefficient. For example, for a SECSED code to perform a 64 bit write operation, which is protecting 512 bits, a computing system is constrained to read 522 bits and then write 74 (64+10) bits, which is highly energy inefficient with at least a nine times increase (e.g., 9.3×) energy overhead consumption increase.

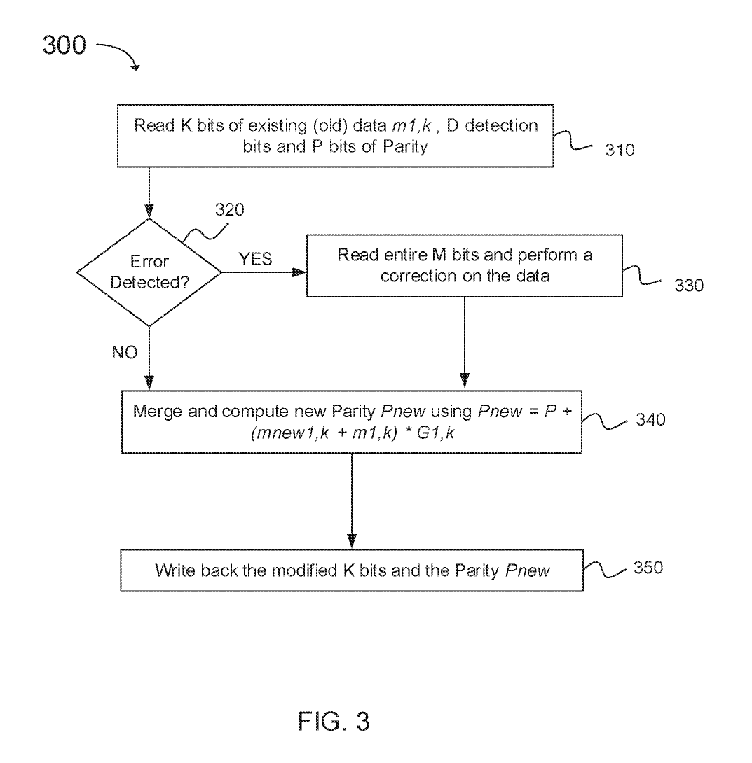

In one aspect, the various embodiments can exploit the linear nature of the parity code and reduces the energy consumption for RMW operation by only reading the data bits, which are written. FIG. 3 depicts a flowchart of a method 300 for performing a partial write operation on K bits of memory protected at an M bit granularity with P bits of parity. The method 300 can be executed as instructions on a machine, where the instructions are included on at least one computer readable medium or one non-transitory machine readable storage medium. The method can include the operation of: reading only 1) the relevant K data bits, 2) the corresponding D detection-only-bits of the K data bits, and 3) the P parity bit protecting an entire line out of the memory, as in block 310. The method can include the operation of: checking and correcting any errors are present in the K bits, such as by using the D error detection-only-parity bits, as in block 320. If there are errors detected, the method can include the operation of: reading the entire M bits and perform an error correction operation on the data, as in block 330. From both blocks 320 and 330, the method can include the operation of: merging new data with old data and computing the new parity P bits using equation (7) (e.g., P^{new}= [symbol] +M^{new}_{1,K}+G_{1,K}+M_{1,K}*G_{1,K}), as illustrated in block 340. The method can include the operation of: writing the relevant K bits and P bits of new parity [symbol] ^{new} to the memory, as in block 350.

It should be noted that in block 320, if the D error detection-only-parity bits indicate an error, the entire line of M bits are read out only for performing the correction. Otherwise, as stated in block 310, only the K bits of old data, the D error detection-only-bits, and the P parity bits are read out, which can significantly increase computing efficiency. That is, since the error case occurrence at block 320 is a relatively rare event and rarely triggered, the associated energy costs are negligible. Thus, using an example of a 64 bit write example, as illustrated above, the method of FIG. 3 reads only 1) the relevant 64 bits of data, 2) the 1 bit D error detection-only-parity bit, and 3) the 10 bits of parity, and then updates and write the modified data back to memory. Thus, various embodiments provide for the read out 75 bits and write back 75 bits, or 150 bits, in comparison to the 596 bits read out and written back in the traditional RMW scheme. This is an almost 4× reduction in energy use.

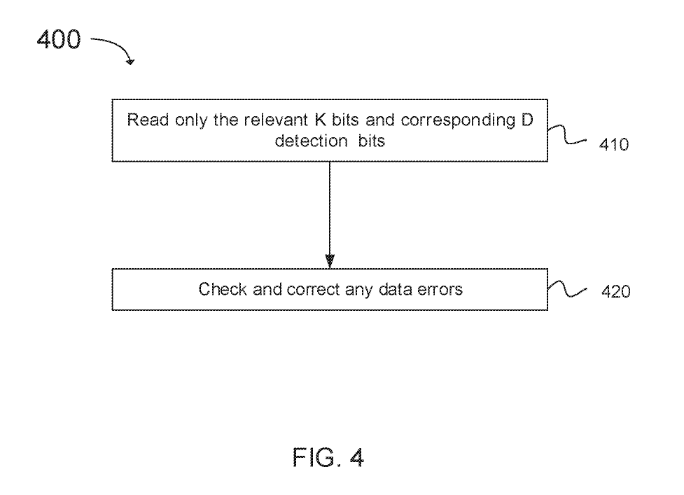

In an additional aspect, for a partial read operation, the various embodiments can substantially reduce the energy costs, as illustrated in FIG. 4. FIG. 4 depicts a flowchart of a method 400 for performing a partial read operation on K bits of memory protected at an M bit granularity with P bits of parity. The method 400 can be executed as instructions on a machine, where the instructions are included on at least one computer readable medium or one non-transitory machine-readable storage medium. The method can include the operation of: reading only the relevant K bits and the corresponding D error detection-only-bits, as in block 410. The method can include the operation of: check and correct if there are any errors in the K bits of data as indicated in the corresponding D error detection-only-bits, as in block 420. Accordingly, the various embodiments can eliminate the constraint to read the entire M bits (e.g., having one or more K bits of data) and the P bits of parity out of the memory. Thus, using the 64-bit of data read operation example, for the 64-bit of data read operation, 522 bits are constrained to be read out, which is an increase in energy consumption of almost 8× times the energy consumption overhead. By contrast, with an embodiment, as illustrated in FIG. 4, the energy overhead for using the same 64-bit of data read operation example is significantly reduced since only 1 bit (e.g., the D error detection-only-parity bit) and only 65 bits are read out of memory as compared to the 596 bits read out in a traditional RMW scheme, which is an energy saving of up to at least eight times (8×).

In relation to area overhead, it should be noted that the ECC data scheme, such as depicted in FIG. 1, does incur extra area overhead due to introducing the D error detection-only-parity bits. Since the D error detection-only-parity bits are detection only parity bits, the corresponding area overhead is much smaller and is significantly more area efficient than the alternative, which is to protect the memory at much lower line sizes. For example, in the SECSED example, as illustrated above, the area overhead is merely an increase of 1.5%. Moreover, the various embodiments do not alter or change any existing ECC logic for performing the new parity P^{new} [symbol] omputation operations. The new parity P^{new} [symbol] ompute operating can use existing encoder hardware with the bits of data not involved in the computation set to zero.

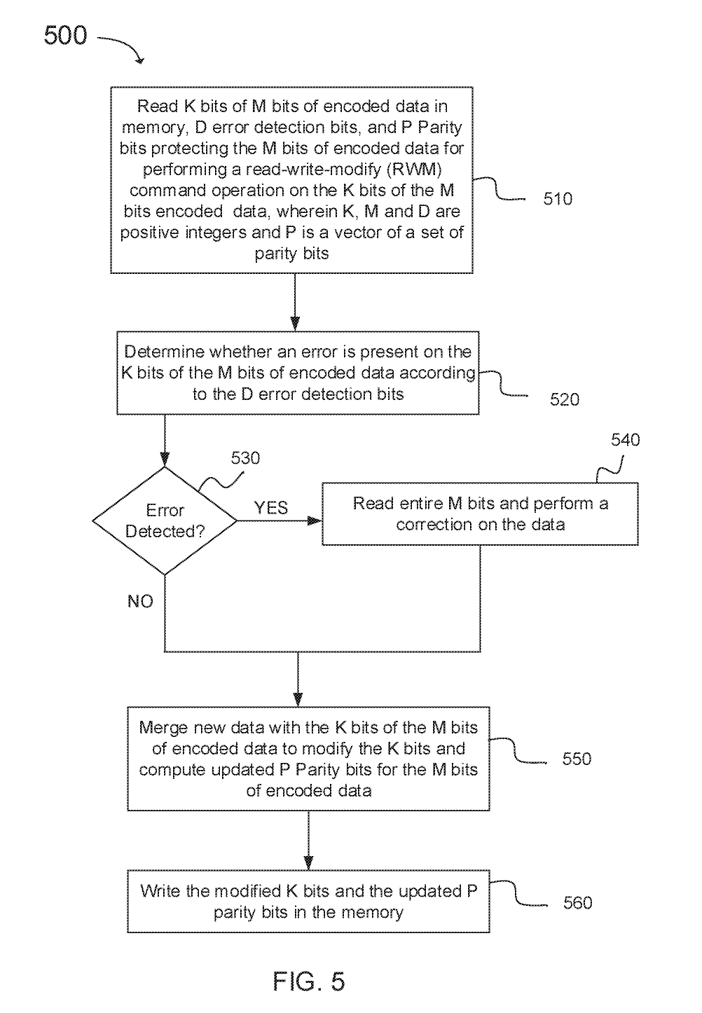

FIG. 5 depicts a flowchart of a method for performing a read-write-modify (RWM) command operation on K bits of memory protected in accordance with an example embodiment. The method 500 can be executed as instructions on a machine, where the instructions are included on at least one computer readable medium or one non-transitory machine-readable storage medium. The method can include the operation of: reading, at the memory controller, K bits of M bits of encoded data in memory, D error detection bits, and P Parity bits protecting the M bits of encoded data for performing a read-write-modify (RWM) command operation on the K bits of the M bits encoded data, wherein K, M and D are positive integers and P is a vector of a set of parity bits, as in block 510. The method can include the operation of: determining, at the memory controller, whether an error is present on the K bits of the M bits of encoded data according to the D error detection bits, as in block 520. If one or more errors are detected, as in block 530, the method can include the operation of: reading the entire M bits and perform an error correction operation on the data, as in block 540. If there no are errors detected, as in block 530, the method can include the operation of: merging, at the memory controller, new data (compared to old, existing data) with the K bits of the M bits of encoded data to modify the K bits and compute updated P Parity bits for the M bits of encoded data, as in block 550. After reading the entire M bits and perform an error correction operation on the data, as in block 540, the method may move to block 550. The method can include the operation of: writing, at the memory controller, the modified K bits and the updated P parity bits in the memory, as in block 560.

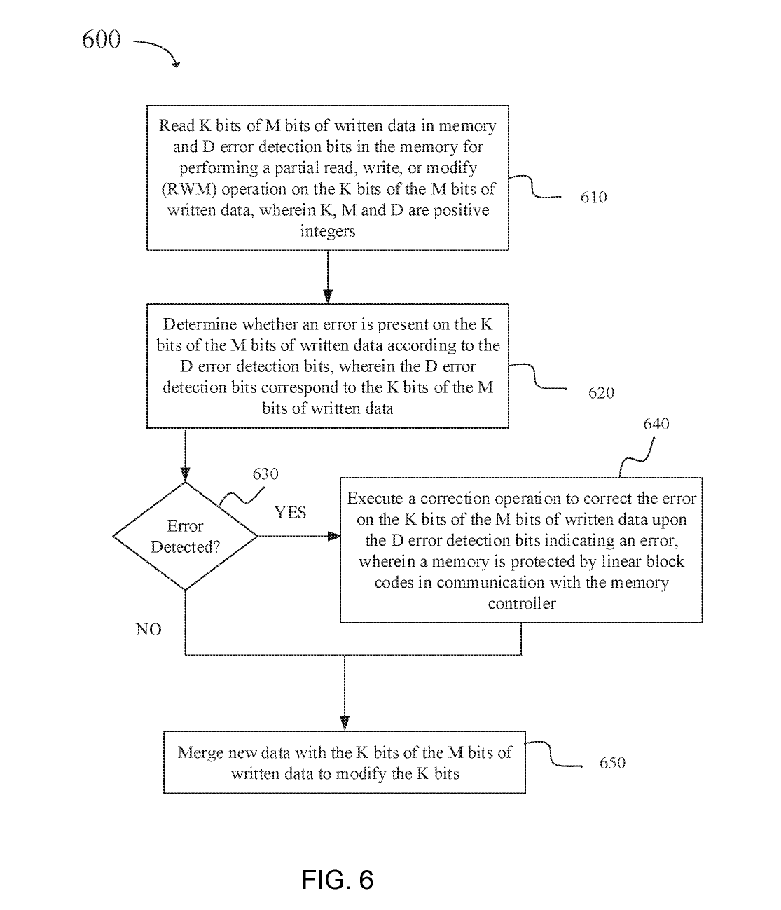

FIG. 6 depicts a flowchart of an additional method 600 for performing a read-write-modify (RWM) command operation on K bits of memory protected in accordance with an example embodiment. The method 600 can be executed as instructions on a machine, where the instructions are included on at least one computer readable medium or one non-transitory machine-readable storage medium. The method can include the operation of: reading, at the memory controller, K bits of M bits of written data in memory and D error detection bits in the memory for performing a partial read, write, or modify (RWM) operation on the K bits of the M bits of written data, wherein K, M and D are positive integers, as in block 610. The method can include the operation of: determining, at the memory controller, whether an error is present on the K bits of the M bits of written data according to the D error detection bits, wherein the D error detection bits correspond to the K bits of the M bits of written data, as in block 620. If one or more errors are detected, as in block 630, the method can include the operation of: executing, at the memory controller, a correction operation to correct the error on the K bits of the M bits of written data upon the D error detection bits indicating an error, wherein a memory is protected by linear block codes in communication with the memory controller, as in block 640. The method can move to block 650 after executing the correction operation, as in block 640. If no error is detected, as in block 630, the method can include the operation of: merging new data with the K bits of the M bits of written data to modify the K bits, as in block 650.

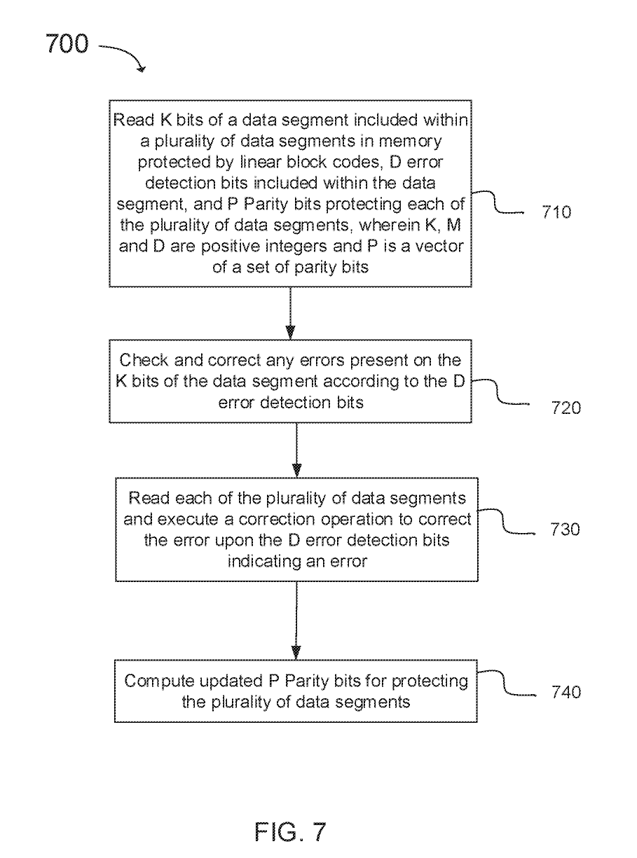

FIG. 7 depicts a flowchart of an additional method 700 for performing a read-write-modify (RWM) command operation on K bits of memory protected in accordance with an example embodiment. The method 700 can be executed as instructions on a machine, where the instructions are included on at least one computer readable medium or one non-transitory machine readable storage medium. The method can include the operation of: reading, at the memory controller, K bits of a data segment included within a plurality of data segments in memory protected by linear block codes, D error detection bits included within the data segment, and P Parity bits protecting each of the plurality of data segments, wherein K, M and D are positive integers and P is a vector of a set of parity bits, as in block 710. The method can include the operation of: checking and correcting, at the memory controller, any errors present on the K bits of the data segment according to the D error detection bits, as in block 720. The method can include the operation of: reading, at the memory controller, each of the plurality of data segments and execute a correction operation to correct the error upon the D error detection bits indicating an error, as in block 730. The method can include the operation of: computing, at the memory controller, updated P Parity bits for protecting the plurality of data segments, as in block 740.

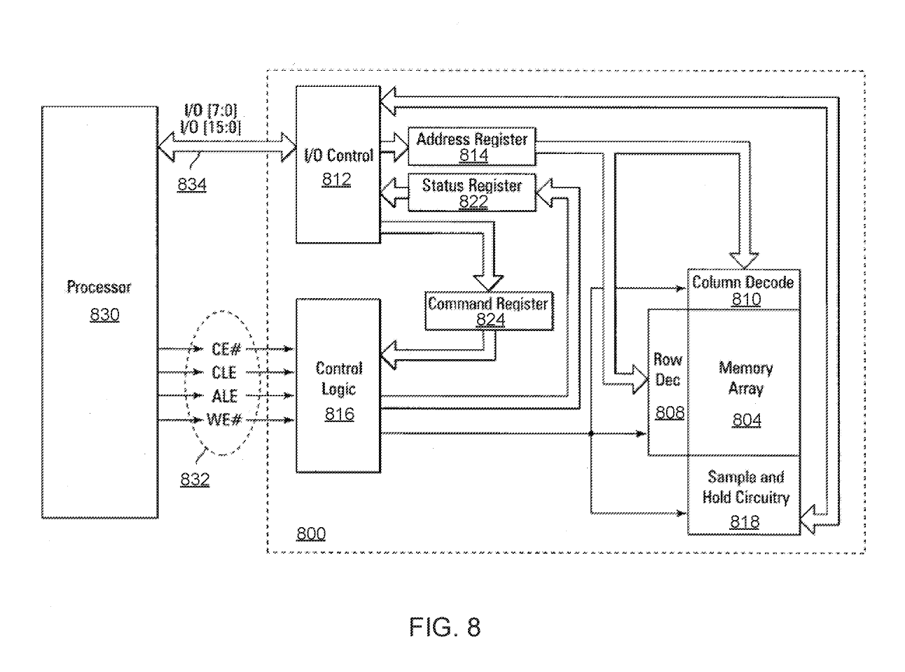

FIG. 8 is a simplified block diagram of a memory device 800 according to an invention embodiment, and on which various methods can be practiced. Memory device 800 includes an array of memory cells 804 arranged in rows and columns. Although the various embodiments will be described primarily with reference to NAND memory arrays, the various embodiments are not limited to a specific architecture of the memory array 804. Some examples of specific array architectures include, NOR arrays, AND arrays, PCM arrays, and virtual ground arrays. In general, however, the embodiments described herein are adaptable to any array architecture permitting generation of a data signal indicative of state of a memory cell, such as through a the threshold voltage.

A row decode circuitry 808 and a column decode circuitry 810 are provided to decode address signals provided to the memory device 800. Address signals are received and decoded to access memory array 804. Memory device 800 also includes input/output (I/O) control circuitry 812 to manage input of commands, addresses and data to the memory device 800 as well as output of data and status information from the memory device 800. An address register 814 is coupled between I/O control circuitry 812 and row decode circuitry 808 and column decode circuitry 810 to latch the address signals prior to decoding. A command register 824 is coupled between I/O control circuitry 812 and control logic 816 to latch incoming commands. Control logic 816 controls access to the memory array 804 in response to the commands and generates status information for an external processor 830 (also known as a memory controller as described earlier). The control logic 816 is coupled to row decode circuitry 808 and column decode circuitry 810 to control the row decode circuitry 808 and column decode circuitry 810 in response to the addresses.

Control logic 816 can be coupled to a sample and hold circuitry 818. The sample and hold circuitry 818 latches data, either incoming or outgoing, in the form of analog data signals. For example, the sample and hold circuitry could contain capacitors or other analog storage devices for sampling either an incoming data signal representing data to be written to a memory cell or an outgoing data signal indicative of the threshold voltage sensed from a memory cell. The sample and hold circuitry 818 can further provide for amplification and/or buffering of the sampled signal to provide a stronger data signal to an external device.

The handling of analog data signals can take an approach where charge levels generated are stored on capacitors. A charge can be stored on a capacitor in response to subjecting it to a data signal indicative of an actual or target threshold voltage of a memory cell for reading or programming, respectively, the memory cell. This charge could then be converted to an analog data signal using a differential amplifier having a grounded input or other reference signal as a second input. The output of the differential amplifier could then be passed to the I/O control circuitry 812 for output from the memory device, in the case of a read operation, or used for comparison during one or more verify operations in programming the memory device. It is noted that the I/O control circuitry 812 could optionally include analog-to-digital conversion functionality and digital-to-analog conversion (DAC) functionality to convert read data from an analog data signal to a digital bit pattern and to convert write data from a digital bit pattern to an analog signal such that the memory device 800 could be adapted for communication with either an analog or digital data interface.

During a programming operation, target memory cells of the memory array 804 are programmed until voltages indicative of their Vt levels match the levels held in the sample and hold circuitry 818. This can be accomplished, as one example, using differential sensing devices to compare the held voltage level to a threshold voltage of the target memory cell. Much like traditional memory programming, programming pulses could be applied to a target memory cell to increase its threshold voltage until reaching or exceeding the desired value. In a read operation, the Vt levels of the target memory cells are passed to the sample and hold circuitry 818 for transfer to an external processor (not shown in FIG. 8) either directly as analog signals or as digitized representations of the analog signals depending upon whether ADC/DAC functionality is provided external to, or within, the memory device.

Threshold voltages of cells can be determined in a variety of manners. For example, an access line, such as those typically referred to as word lines, voltage could be sampled at the point when the target memory cell becomes activated. Alternatively, a boosted voltage could be applied to a first source/drain side of a target memory cell, and the threshold voltage could be taken as a difference between its control gate voltage and the voltage at its other source/drain side. By coupling the voltage to a capacitor, charge would be shared with the capacitor to store the sampled voltage. Note that the sampled voltage need not be equal to the threshold voltage, but merely indicative of that voltage. For example, in the case of applying a boosted voltage to a first source/drain side of the memory cell and a known voltage to its control gate, the voltage developed at the second source/drain side of the memory cell could be taken as the data signal as the developed voltage is indicative of the threshold voltage of the memory cell.

Sample and hold circuitry 818 can include caching, i.e., multiple storage locations for each data value, such that the memory device 800 can be reading a next data value while passing a first data value to the external processor, or receiving a next data value while writing a first data value to the memory array 804. A status register 822 is coupled between I/O control circuitry 812 and control logic 816 to latch the status information for output to the external processor.

Memory device 800 receives control signals at control logic 816 over a control link 832. The control signals can include a chip enable CE#, a command latch enable CLE, an address latch enable ALE, and a write enable WE#. Memory device 800 can receive commands (in the form of command signals), addresses (in the form of address signals), and data (in the form of data signals) from an external processor over a multiplexed input/output (I/O) bus 834 and output data to the external processor over I/O bus 834.

In a specific example, commands are received over input/output (I/O) pins [7:0] of I/O bus 834 at I/O control circuitry 812 and are written into command register 824. The addresses are received over input/output (I/O) pins [7:0] of bus 834 at I/O control circuitry 812 and are written into address register 814. The data can be received over input/output (I/O) pins [7:0] for a device capable of receiving eight parallel signals, or input/output (I/O) pins [15:0] for a device capable of receiving sixteen parallel signals, at I/O control circuitry 812 and are transferred to sample and hold circuitry 818. Data also can be output over input/output (I/O) pins [7:0] for a device capable of transmitting eight parallel signals or input/output (I/O) pins [15:0] for a device capable of transmitting sixteen parallel signals. It will be appreciated by those skilled in the art that additional circuitry and signals can be provided, and that the memory device of FIG. 8 has been simplified to help focus on the embodiments of the disclosure.

While FIG. 8 has been described with respect to sample and hold circuitry 818, it should be understood that the control logic 816 could be coupled to data latches instead of sample and hold circuitry 818 without departing from the scope of the disclosure. During a write operation, target memory cells of the memory array 804 are programmed, for example using two sets of programming pulses as described above, until voltages indicative of their Vt levels match the data held in the data latches. This can be accomplished, as one example, using differential sensing devices to compare the held data to a threshold voltage of the target memory cell.

Additionally, while the memory device of FIG. 8 has been described in accordance with popular conventions for receipt and output of the various signals, it is noted that the various embodiments are not limited by the specific signals and I/O configurations described. For example, command and address signals could be received at inputs separate from those receiving the data signals, or data signals could be transmitted serially over a single I/O line of I/O bus 934. Because the data signals represent bit patterns instead of individual bits, serial communication of an 8-bit data signal could be as efficient as parallel communication of eight signals representing individual bits.

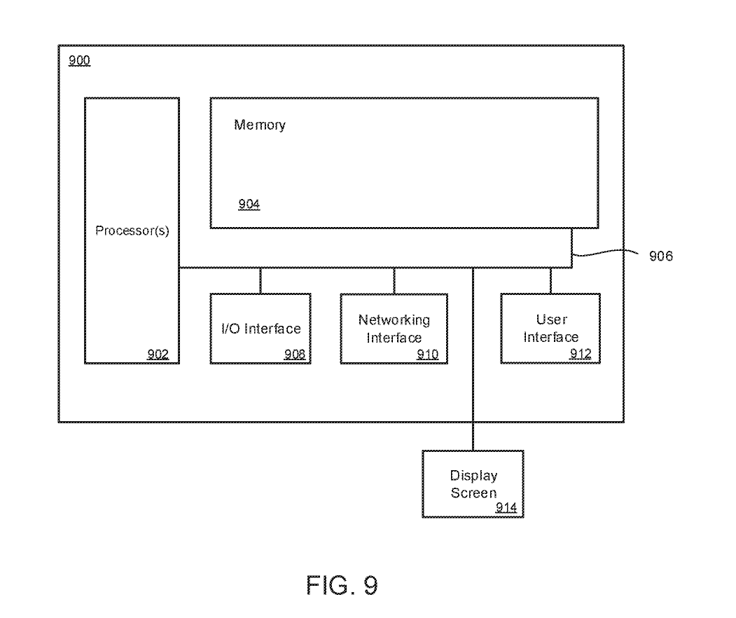

FIG. 9 illustrates a general computing system or device 900 that can be employed in the various embodiments. The computing system 900 can include a processor 902 in communication with a memory 904. The memory 904 can include any device, combination of devices, circuitry, and the like that is capable of storing, accessing, organizing and/or retrieving data. Non-limiting examples include SANs (Storage Area Network), cloud storage networks, volatile or non-volatile RAM, phase change memory, optical media, hard-drive type media, and the like, including combinations thereof.

The computing system or device 900 additionally includes a local communication interface 906 for connectivity between the various components of the system. For example, the local communication interface 906 can be a local data bus and/or any related address or control busses as may be desired.

The computing system or device 900 can also include an I/O (input/output) interface 908 for controlling the I/O functions of the system, as well as for I/O connectivity to devices outside of the computing system 900. A network interface 910 can also be included for network connectivity. The network interface 910 can control network communications both within the system and outside of the system. The network interface can include a wired interface, a wireless interface, a Bluetooth interface, optical interface, and the like, including appropriate combinations thereof. Furthermore, the computing system 900 can additionally include a user interface 912, a display device 914, as well as various other components that would be beneficial for such a system.

The processor 902 can be a single or multiple processors, and the memory 904 can be a single or multiple memories. The local communication interface 906 can be used as a pathway to facilitate communication between any of a single processor, multiple processors, a single memory, multiple memories, the various interfaces, and the like, in any useful combination.

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device). When a program code is loaded into and executed by a machine, such as a computer, the machine becomes an apparatus for practicing the various techniques.

Circuitry can include hardware, firmware, program code, executable code, computer instructions, and/or software. A non-transitory computer readable storage medium can be a computer readable storage medium that does not include signal. In the case of program code execution on programmable computers, the computing device can include a processor, a storage medium readable by the processor (including volatile and non-volatile memory and/or storage elements), at least one input device, and at least one output device. The volatile and non-volatile memory and/or storage elements can be a RAM, EPROM, flash drive, optical drive, magnetic hard drive, solid state drive, or other medium for storing electronic data. Any node and wireless devices can also include a transceiver module, a counter module, a processing module, and/or a clock module or timer module. One or more programs that can implement or utilize the various techniques described herein can use an application programming interface (API), reusable controls, and the like. Such programs can be implemented in a high level procedural or object oriented programming language to communicate with a computer system. However, the program(s) can be implemented in assembly or machine language, if desired. In any case, the language can be a compiled or interpreted language, and combined with hardware implementations. Exemplary systems or devices can include without limitation, laptop computers, tablet computers, desktop computers, smart phones, computer terminals and servers, storage databases, and other electronics which utilize circuitry and programmable memory, such as household appliances, smart televisions, digital video disc (DVD) players, heating, ventilating, and air conditioning (HVAC) controllers, light switches, and the like.

Although not depicted, system 900 can use a battery or other power source, such as renewable energy (solar panels), or include circuitry for access to a wall socket or charging port (wired or wireless).

### Examples

The following examples pertain to specific invention embodiments and point out specific features, elements, or steps that can be used or otherwise combined in achieving such embodiments.

In one example there is provided an apparatus comprising:
a memory controller with circuitry configured to:
   read K bits of M bits of encoded data from memory, D error detection bits, and P Parity bits that protect the M bits of encoded data;
   perform a read-write-modify (RWM) command operation on the K bits of the M bits encoded data, wherein K, M and D are positive integers and P is a vector of a set of parity bits;
   determine whether an error is present on the K bits of the M bits of encoded data according to the D error detection bits;
   merge new data with the K bits of the M bits of encoded data to modify the K bits and compute updated P Parity bits for the M bits of encoded data; and
   write the modified K bits and the updated P parity bits in the memory; and
   an interface to the memory controller.

In one example of an apparatus, the D error detection bits are adjacent to the K bits of the M bits of encoded data.

In one example of an apparatus, the D error detection bits are a set of error detection only parity bits adjacent to each series of K bits of the M bits of encoded data.

In one example of an apparatus, the memory controller is configured to read the M bits of encoded data and execute a correction operation to correct an error when the D error detection bits detect an error.

In one example of an apparatus, further comprises the memory, wherein the memory controller comprises logic further configured to compute updated P Parity bits in the memory according to equation P^{new}=P=(M_{1,k}^{new}+M_{1,k})* [symbol] _{1,k}, where P^{new} is the update P Parity bits, M_{1,k}^{new} is the a number of bits of new data, M_{1,k} is a number of data bits that are encoded, and G is a number of corresponding rows of a generator matrix, wherein a number of columns in the generator matrix is dependent on a number of the P Parity bits that may be mandated by a linear block code.

In one example of an apparatus, further comprises the memory, the memory is a scratchpad memory, an on-chip memory, or an off-chip memory, byte addressable memory, memory devices that use chalcogenide phase change material, multi-threshold level NAND flash memory, NOR flash memory, single or multi-level PCM, a resistive memory, nanowire memory, ferroelectric transistor random access memory (FeTRAM), magnetoresistive random access memory (MRAM) memory that incorporates memristor technology, or spin transfer torque (STT)-MRAM.

In one example of an apparatus, the apparatus further comprises one or more of:

the NVM, the NVM communicatively coupled to the memory controller;

a processor communicatively coupled to the memory controller;

a network interface communicatively coupled to a processor;

a display communicatively coupled to a processor; or

a battery coupled to a processor.

In one example there is provided, a data storage system operable to provide efficient read-write-modify (RMW) operations for memories protected by linear block codes, the data storage system comprising:

a memory controller comprising logic to:
read K bits of M bits of data from memory and D error detection bits from the memory;
perform a partial read, write, or modify (RWM) operation on the K bits of the M bits of written data, wherein K, M and D are positive integers;
determine whether an error is present on the K bits of the M bits of written data according to the D error detection bits, wherein the D error detection bits correspond to the K bits of the M bits of written data; and
execute a correction operation to correct the error on the K bits of the M bits of written data upon the D error detection bits indicating an error, wherein a memory is protected by linear block codes in communication with the memory controller; and
an interface to the memory controller.

In one example of a data storage system, the memory controller is configured to read the K bits of M bits of written data, the D error detection bits, and P Parity bits protecting the M bits of written data; wherein P is a vector of a set of parity bits.

In one example of a data storage system, the memory controller is configured to: merge new data with the K bits of the M bits of written data to modify the K bits; and/or write the modified K bits and the updated P parity bits in the memory.

In one example of a data storage system, the memory controller is configured to read the M bits of written data in the memory upon the D error detection bits indicating an error.

In one example of a data storage system, the memory controller comprises logic further configured to:
compute new P Parity bits for protecting the M bits of written data, wherein the new P Parity bits replace P Parity bits protecting the M bits of written data; and
replace the P parity bits in the memory with the new P Parity bits.

In one example of a data storage system, wherein the memory controller comprises logic further configured to compute the new P Parity bits protecting the M bits of written data according to equation P^{new}=P=(M_{1,k}^{new}+M_{1,k})* [symbol] _{1,k}, where P^{new} are new P Parity bits, M_{1,k}^{new} is the a number of bits of new data, M_{1,k} is a number of data bits that are written and encoded, and G corresponds to a number of rows of a generator matrix.

In one example of a data storage system, wherein the D error detection bits are a set of error detection only parity bits following each series of K bits of the M bits of written data.

In one example of a data storage system, wherein the D error detection bits are stored in the memory adjacent to each series of 8 bits of the M bits of written data.

In one example of a data storage system, further comprising the protected memory, wherein the protected memory is an error correction code protected memory, a scratchpad memory, a cache, an on-chip memory, or an off-chip memory, byte addressable memory, memory devices that use chalcogenide phase change material, multi-threshold level NAND flash memory, NOR flash memory, single or multi-level PCM, a resistive memory, nanowire memory, ferroelectric transistor random access memory (FeTRAM), magnetoresistive random access memory (MRAM) memory that incorporates memristor technology, or spin transfer torque (STT)-MRAM.

In one example of a data storage system, further comprising one or more of:

the NVM, the NVM communicatively coupled to the memory controller;

a processor communicatively coupled to the memory controller;

a network interface communicatively coupled to a processor;

a display communicatively coupled to a processor; or

a battery coupled to a processor.

In one example there is provided, a method comprising:
under control of at least one processor and memory configured with executable instructions that:
read K bits of a data segment included within a plurality of data segments in memory protected by linear block codes, D error detection bits included within the data segment, and P Parity bits protecting each of the plurality of data segments, wherein K, M and D are positive integers and P is a vector of a set of parity bits;
determine whether an error is present on the K bits of the data segment according to the D error detection bits;
read each of the plurality of data segments and execute a correction operation to correct the error upon the D error detection bits indicating an error; and
compute updated P Parity bits for protecting the plurality of data segments.

In one example of a method for reducing energy consumption for partial read-write-modify (RWM) command operations for memory protected by linear block codes, wherein the executable instructions further:
merge new data with the K bits of the data segment to modify the K bits; and
write the modified K bits and the updated P parity bits in the memory, wherein the updated P Parity bits replace the P Parity bits protecting the plurality of data segments.

In one example of a method for reducing energy consumption for partial read-write-modify (RWM) command operations for memory protected by linear block codes, wherein D error detection bits are a set of detection only parity bits located after each series of K bits in each of the plurality of data segments.

In one example of a method for reducing energy consumption for partial read-write-modify (RWM) command operations for memory protected by linear block codes, wherein the data segment includes the D error detection bits and 8 bits encoded data.

In one example of a method for reducing energy consumption for partial read-write-modify (RWM) command operations for memory protected by linear block codes, wherein the executable instructions further compute the updated P Parity bits protecting each of the plurality of data segments according to equation P^{new}=P=(M_{1,k}^{new}+M_{1,k})* [symbol] _{1,k}, where P^{new} is the update P Parity bits, M_{1,k}^{new} is the a number of bits of new data, M_{1,k} is a number of data bits that are encoded, and G is a number of corresponding rows of a generator matrix.

In one example of a method for reducing energy consumption for partial read-write-modify (RWM) command operations for memory protected by linear block codes, wherein the executable instructions further execute the correction operation to correct the error using an error correction code.

While the forgoing examples are illustrative of the principles of invention embodiments in one or more particular applications, it will be apparent to those of ordinary skill in the art that numerous modifications in form, usage and details of implementation can be made without the exercise of inventive faculty, and without departing from the principles and concepts of the disclosure.

What is claimed is:

1. An apparatus, comprising:
a memory controller with circuitry configured to:
read K bits of M bits of encoded data from memory, D error detection bits, and P Parity bits that protect the M bits of encoded data;
perform a read-write-modify (RWM) command operation on the K bits of the M bits encoded data, wherein K, M and D are positive integers and P is a vector of a set of parity bits;
determine whether an error is present on the K bits of the M bits of encoded data according to the D error detection bits;
merge new data with the K bits of the M bits of encoded data to modify the K bits and compute updated P Parity bits for the M bits of encoded data; and
write the modified K bits and the updated P parity bits in the memory; and
an interface to the memory controller.

2. The apparatus of claim 1, wherein the D error detection bits are adjacent to the K bits of the M bits of encoded data.

3. The apparatus of claim 1, wherein the D error detection bits are a set of error detection only parity bits adjacent to each series of K bits of the M bits of encoded data.

4. The apparatus of claim 1, wherein the D error detection bits follow after each series of 8 bits of the M bits of encoded data.

5. The apparatus of claim 1, wherein the memory controller is configured to read the M bits of encoded data and execute a correction operation to correct an error when the D error detection bits detect an error.

6. The apparatus of claim 1, wherein the memory controller comprises logic further configured to compute updated P Parity bits in the memory according to equation P^{new}=P=(M_{1,k}^{new}+M_{1,k})*G_{1,k}, where P^{new} is the update P Parity bits, M_{1,k}^{new} is the a number of bits of new data, M_{1,k} is a number of data bits that are encoded, and G is a number of corresponding rows of a generator matrix, wherein a number of columns in the generator matrix is dependent on a number of the P Parity bits required by a linear block code.

7. The apparatus of claim 1, further comprising the memory, wherein the memory comprises an error correction code protected memory.

8. The apparatus of claim 1, further comprising the memory, wherein the memory comprises one or more of a scratchpad memory, an on-chip memory, or an off-chip memory, byte addressable memory, memory devices that use chalcogenide phase change material, multi-threshold level NAND flash memory, NOR flash memory, single or multi-level PCM, a resistive memory, nanowire memory, ferroelectric transistor random access memory (FeTRAM), magnetoresistive random access memory (MRAM) memory that incorporates memristor technology, or spin transfer torque (STT)-MRAM.

9. The apparatus of claim 1, further comprising one or more of:
a non-volatile memory (NVM), the NVM being communicatively coupled to the memory controller;
a processor communicatively coupled to the memory controller;
a network interface communicatively coupled to a processor;
a display communicatively coupled to a processor; or
a battery coupled to a processor.

10. A data storage system comprising:
a memory controller comprising logic to:
read K bits of M bits of data from memory and D error detection bits from the memory;
perform a partial read, write, or modify (RWM) operation on the K bits of the M bits of written data, wherein K, M and D are positive integers;
determine whether an error is present on the K bits of the M bits of written data according to the D error detection bits, wherein the D error detection bits correspond to the K bits of the M bits of written data; and
execute a correction operation to correct the error on the K bits of the M bits of written data upon the D error detection bits indicating an error, wherein a memory is protected by linear block codes in communication with the memory controller; and
an interface to the memory controller.

11. The data storage system of claim 10, wherein the memory controller is configured to read the K bits of M bits of written data, the D error detection bits, and P Parity bits protecting the M bits of written data, wherein P is a vector of a set of parity bits.

12. The data storage system of claim 11, wherein the memory controller is configured to:
merge new data with the K bits of the M bits of written data to modify the K bits; and
write the modified K bits and the updated P parity bits in the memory.

13. The data storage system of claim 10, wherein the memory controller is configured to read the M bits of written data in the memory upon the D error detection bits indicating an error.

14. The data storage system of claim 10, wherein the memory controller comprises logic further configured to:
compute new P Parity bits for protecting the M bits of written data, wherein the new P Parity bits replace P Parity bits protecting the M bits of written data; and
replace the P parity bits in the memory with the new P Parity bits.

15. The data storage system of claim 14, wherein the memory controller comprises logic further configured to compute the new P Parity bits protecting the M bits of written data according to equation P^{new}=P=(M_{1,k}^{new}+M_{1,k})*G_{1,k}, where P^{new} are new P Parity bits, M_{1,k}^{new} is the a number of bits of new data, M_{1,k} is a number of data bits that are written and encoded, and G corresponds to a number of rows of a generator matrix.

16. The data storage system of claim 10, wherein the D error detection bits are a set of error detection only parity bits following each series of K bits of the M bits of written data.

17. The data storage system of claim 10, wherein the D error detection bits are stored in the memory adjacent to each series of 8 bits of the M bits of written data.

18. The data storage system of claim 10, further comprising the protected memory, wherein the protected memory is an error correction code protected memory, a scratchpad memory, a cache, an on-chip memory, or an off-chip memory, byte addressable memory, memory devices that use chalcogenide phase change material, multi-threshold level NAND flash memory, NOR flash memory, single or multi-level PCM, a resistive memory, nanowire memory, ferroelectric transistor random access memory (FeTRAM), magnetoresistive random access memory (MRAM) memory that incorporates memristor technology, or spin transfer torque (STT)-MRAM.

19. The data storage system of claim 10, further comprising one or more of:
a non-volatile memory (NVM), the NVM being communicatively coupled to the memory controller;
a processor communicatively coupled to the memory controller;
a network interface communicatively coupled to a processor;
a display communicatively coupled to a processor; or
a battery coupled to a processor.

20. A method comprising:
under control of at least one processor and memory configured with executable instructions that:
read K bits of a data segment included within a plurality of data segments in memory protected by linear block codes, D error detection bits included within the data segment, and P Parity bits protecting each of the plurality of data segments, wherein K, M and D are positive integers and P is a vector of a set of parity bits;
determine whether an error is present on the K bits of the data segment according to the D error detection bits;
read each of the plurality of data segments and execute a correction operation to correct the error upon the D error detection bits indicating an error; and
compute updated P Parity bits for protecting the plurality of data segments.

21. The method of claim 20, wherein the executable instructions further:
merge new data with the K bits of the data segment to modify the K bits; and
write the modified K bits and the updated P parity bits in the memory, wherein the updated P Parity bits replace the P Parity bits protecting the plurality of data segments.

22. The method of claim 20, wherein D error detection bits are a set of detection only parity bits located after each series of K bits in each of the plurality of data segments.

23. The method of claim 20, wherein the data segment includes the D error detection bits and 8 bits encoded data.

24. The method of claim 20, wherein the executable instructions further compute the updated P Parity bits protecting each of the plurality of data segments according to equation P^{new}=P=(M_{1,k}^{new}+M_{1,k})*G_{1,k}, where P^{new} is the update P Parity bits, M_{1,k}^{new} is the a number of bits of new data, M_{1,k} is a number of data bits that are encoded, and G is a number of corresponding rows of a generator matrix.

25. The method of claim 20, wherein the executable instructions further execute the correction operation to correct the error using an error correction code.
